(19) United States
(12) Patent Application Publication
(10) Pub. No.: US 2013/0210173 A1
(43) Pub. Date: Aug. 15, 2013

(54) Multiple Zone Temperature Control for CMP

(71) Applicants: Jiann Lih Wu, Hsin-Chu City (TW); Bo-I Lee, Sindian City (TW); Soon Kang Huang, Hsin Chu (TW); Chih-I Peng, Hsinchu City (TW); Chi-Ming Yang, Hsinchu City (TW); Chin-Hsiang Lin, Hsinchu (TW)

(72) Inventors: Jiann Lih Wu, Hsin-Chu City (TW); Bo-I Lee, Sindian City (TW); Soon Kang Huang, Hsin Chu (TW); Chih-I Peng, Hsinchu City (TW); Chi-Ming Yang, Hsinchu City (TW); Chin-Hsiang Lin, Hsinchu (TW)

(73) Assignee: Taiwan Semiconductor Manufacturing Co., Ltd., Hsin-Chu (TW)

(21) Appl. No.: 13/372,872

(22) Filed: Feb. 14, 2012

(51) Int. Cl. H01L 21/66; B24B 49/00

(52) U.S. Cl. 438/10; 451/5; 257/E21.531

(57) ABSTRACT

To provide improved planarization, techniques in accordance with this disclosure include a CMP station that includes a plurality of concentric temperature control elements arranged over a number of concentric to-be-polished wafer surfaces. During polishing, a wafer surface planarity sensor monitors relative heights of the concentric to-be-polished wafer surfaces, and adjusts the temperatures of the concentric temperature control elements to provide an extremely well planarized wafer surface. Other systems and methods are also disclosed.

### BACKGROUND

Over the last four decades, the density of integrated circuits has increased by a relation known as Moore's law. Stated simply, Moore's law says that the number of transistors on integrated circuits (ICs) doubles approximately every 18 months. Thus, as long as the semiconductor industry can continue to uphold this simple “law,” ICs double in speed and power approximately every 18 months. In large part, this remarkable increase in the speed and power of ICs has ushered in the dawn of today's information age.

Unlike laws of nature, which hold true regardless of mankind's activities, Moore's law only holds true only so long as innovators overcome the technological challenges associated with it. One of the advances that innovators have made in recent decades is to use chemical mechanical polishing (CMP) to planarize layers used to build up ICs, thereby helping to provide more precisely structured device features on the ICs.

To limit imperfections in planarization, improved planarization processes are described herein.

### BRIEF DESCRIPTION OF THE DRAWINGS

FIG. 1 shows a block diagram of a CMP system in accordance with some embodiments.

FIG. 2 is a top view of a semiconductor wafer which includes a plurality of concentric to-be-polished surfaces.

FIG. 3 is a top view of FIG. 2's semiconductor wafer with a plurality of concentric temperature control elements arranged proximate thereto.

FIG. 4 shows a block diagram of another CMP system in accordance with some embodiments.

FIG. 5 is a cross sectional view illustrating a wafer being polished by FIG. 4's CMP system in accordance with some embodiments.

FIG. 6 is a chart illustrating one example of how a wafer can be polished in time.

FIG. 7 is a flow diagram illustrating a method of performing a planarization process in accordance with some embodiments.

### DETAILED DESCRIPTION

The present disclosure will now be described with reference to the drawings wherein like reference numerals are used to refer to like elements throughout, and wherein the illustrated structures are not necessarily drawn to scale. It will be appreciated that this detailed description and the corresponding figures do not limit the scope of the present disclosure in any way, and that the detailed description and figures merely provide a few examples to illustrate some ways in which the inventive concepts can manifest themselves.

FIG. 1 shows a block diagram of a CMP system 100 in accordance with some embodiments of the present disclosure. The CMP system 100 includes a CMP station 102, which includes a polishing head 104 to retain one or more semiconductor wafers 106 during CMP operations. The polishing head 104 includes a number of concentric temperature control elements 108, such as heating or cooling elements, which are proximate to a plurality of concentric to-be-polished wafer surfaces, respectively.

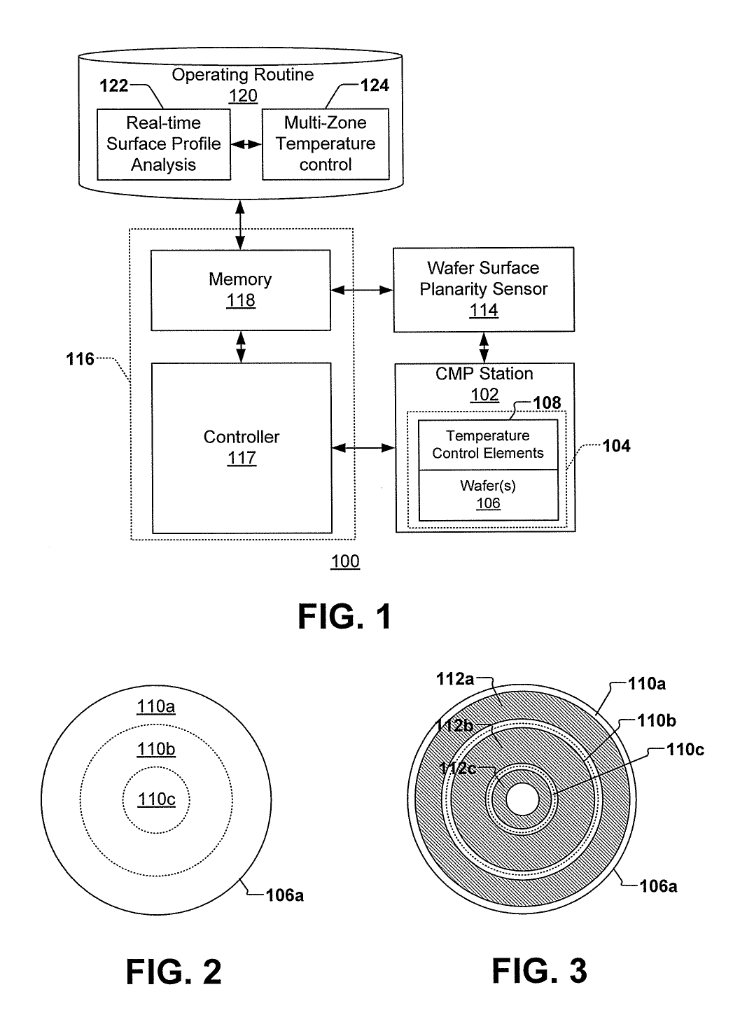

FIG. 2 shows a wafer 106a with a number of concentric to-be-polished surfaces 110a-110c, while FIG. 3 shows concentric temperature control elements 112a-112c located proximate to the to-be-polished surfaces 110a-110c, respectively. It will be appreciated that although FIGS. 2-3 show three concentric to-be-polished wafer surfaces and three corresponding temperature control elements, any number of surfaces and temperature control elements are contemplated as falling within the scope of the invention.

Referring back to FIG. 1, during polishing, wafer surface planarity sensor 114 measures planarity of respective to-be-polished wafer surfaces (e.g., 110a-110c in FIG. 2). Feedback path 116 couples wafer surface planarity sensor 114 to the temperature control elements 108. Feedback path 116 includes controller 117 and memory 118, wherein memory 118 stores instructions of operating routine 120. The operating routine 120 includes a real-time surface profile analysis module 122 and a multi-zone temperature control module 124. The real-time surface profile analysis module 122 analyzes the planarity of to-be-polished wafer surfaces as measured by sensor 114. Based on the planarity (or lack thereof) for the respective to-be-polished wafer surfaces, multi-zone temperature control module 124 can change temperatures for respective temperature control elements, which are proximate to the respective to-be-polished wafer surfaces. Because the CMP polishing rate is proportional to temperature, this surface-by-surface temperature control scheme helps to provide extremely accurate planarization. For example, if a to-be-polished wafer surface (e.g., 110b in FIG. 2) is relatively high (e.g., a hillock), the temperature of the corresponding temperature control element (e.g., 112b in FIG. 3) can be increased relative to neighboring temperature control elements (e.g., 112a, 112c in FIG. 3). Conversely, if the to-be-polished wafer surface (e.g., 110b in FIG. 2) is relatively low (e.g., a valley), the temperature of the corresponding temperature control element (e.g., 112b in FIG. 3) can be decreased relative to neighboring temperature control regions (e.g., 112a, 112c in FIG. 3). Thus, the temperatures for the individual to-be polished wafer surfaces can be independently varied in a continuous and ongoing manner to tailor their respective polish rates during polishing, thereby providing extremely uniform planarization.

Although FIG. 1 shows the real-time-surface profile analysis module 122 and multi-zone temperature control module 124 as software modules, these modules can also be implemented as purely hardware modules (e.g., application specific integrated circuits (ASICs) or combinations of hardware and software. In addition, the other illustrated blocks can include multiple instantiations that can be inter-mixed in any number of ways. For example, memory 118 can be physically present in wafer surface planarity sensor 114, in CMP station 102, as well as in controller 117, and operating routine 120 can commensurately distributed over this memory as appropriate.

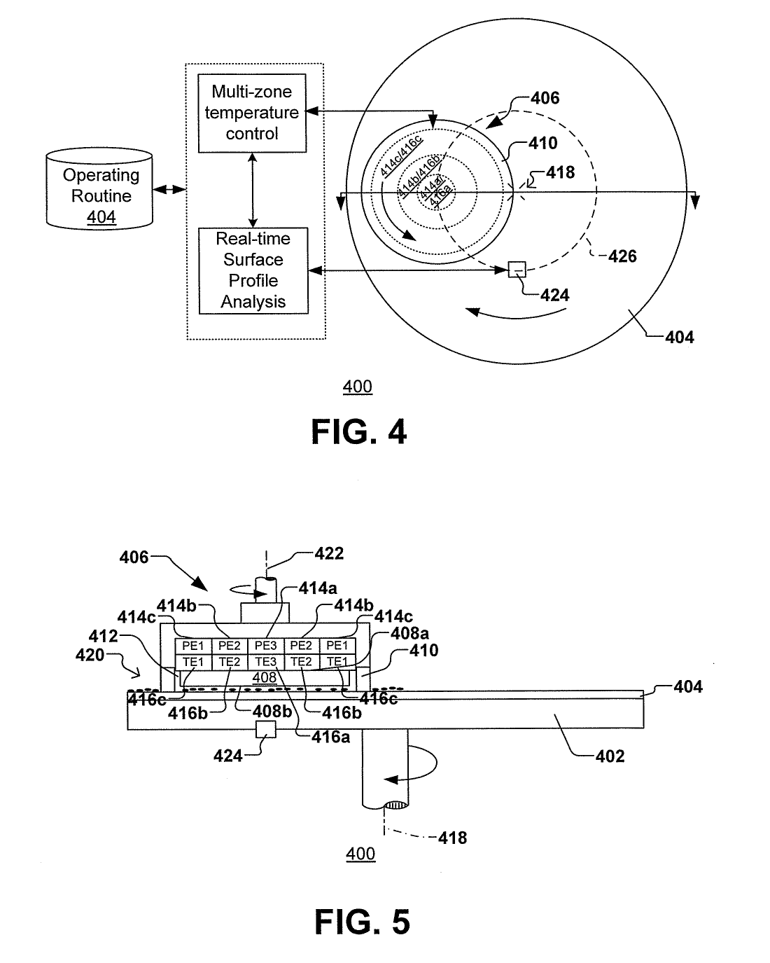

FIGS. 4-5 show a top view and cross-sectional side view, respectively, of another CMP station 400 in accordance with some embodiments. CMP station 400 comprises platen 402, polishing pad 404 supported by platen 402, and polishing head 406 to hold wafer 408 on polishing pad 404 during polishing. Polishing head 406 includes an annular retaining ring 410, inside of which a pocket 412 houses wafer 408. A plurality of concentric, variable-pressure elements (PE) 414a-414c and a plurality of concentric, variable-temperature elements (TE) 416a-416c are also included on polishing head 406. The variable pressure elements 414, which are proximate to pocket 412, exert independent amounts of suction or pressure onto corresponding concentric regions on the back-side of the wafer 408a. The variable temperature elements 416 similarly exert independent temperatures to slurry regions proximate to respective concentric surfaces on the front-side of wafer 408b. These concentric surfaces on the front of the wafer 408b may also be called “to-be-polished” wafer surfaces.

In some CMP processes, wafer 408 is held inside pocket 412 with upward suction applied to wafer's backside by variable pressure elements 414 so as to keep the wafer 408 raised above the lower face of retaining ring 410. Platen 402 is then rotated about platen axis 418, which correspondingly rotates polishing pad 404. Abrasive slurry 420 in then dispensed onto the polishing pad 404. A spindle motor (not shown) then begins rotating polishing head 406 around spindle axis 422. Meanwhile, polishing head 406 is lowered, retaining ring 410 is pressed onto polishing pad 404, with wafer 408 recessed just long enough for polishing head 406 to reach polishing speed. When polishing head 406 reaches wafer polishing speed, wafer 408 is lowered facedown inside pocket 412 to contact the surface of polishing pad 404 and/or abrasive slurry 420, so that the wafer 408 is substantially flush with and constrained outwardly by retaining ring 410. Retaining ring 410 and wafer 408 continue to spin relative to polishing pad 404, which is rotating along with platen 402. This dual rotation, in the presence of the downforce applied to wafer 408 and the abrasive slurry 420, cause the wafer 408 to be gradually planarized.

During polishing, planarity sensor 424 measures the heights of the respective concentric to-be-polished wafer regions. In FIGS. 4-5's embodiment, as the platen 402 (to which the planarity sensor 424 is mounted) and polishing head 406 undergo dual rotation, the planarity sensor 424 traces a path 426 that traverses the concentric to-be-polished wafer surfaces. Thus, as the platen 402 and polishing head 406 rotate with respect to one another during polishing, the planarity sensor 424 naturally passes over the respective to-be-polished wafer surfaces in time, and can continuously monitor the heights of these surfaces as it passes thereover.

In some embodiments, an uppermost conductive layer whose planarity to be measured is a copper layer, an aluminum layer, or polysilicon layer, for example. In such embodiments, the planarity sensor 424 can comprise an inductive sensor that measures Eddy currents induced in the to-be-polished wafer surfaces as the sensor 424 passes thereover. The magnitude of these Eddy currents correspond to the distance between the sensor 424 and a closest surface of the upper conductive layer, thereby allowing the planarity of the wafer 408 to be measured. In other embodiments, optical measurements or other techniques can be used to measure planarity. For example, in some embodiments, the planarity can be measured by polarized scatterometry techniques, which used transverse electric and transverse magnetic waves to extract complete profile information for the to-be-polished wafer surfaces.

The variable-pressure elements (PE) 414a-414c variable-temperature elements (TE) 416a-416c can take various forms depending on the implementation. For example, in some embodiments the concentric PEs and TEs can be implemented as concentric bladders (e.g., inner tubes), which have independent fluid pressures and temperatures. In other embodiments, the pressures exerted by the pressure elements can be provided by a motor, a hydraulic-element, or an electric-field or magnetic field generator. The temperature elements can also be established by resistive heating, such as by passing a current or voltage through a resistance until a pre-determined temperature is reached.

After CMP, polishing head 406 and wafer 408 are lifted, and polishing pad 404 is generally subjected to a high-pressure spray of deionized water to remove slurry residue and other particulate matter from the pad 404. Other particulate matter may include wafer residue, CMP slurry, oxides, organic contaminants, mobile ions and metallic impurities. Wafer 408 is then subjected to a post-CMP cleaning process.

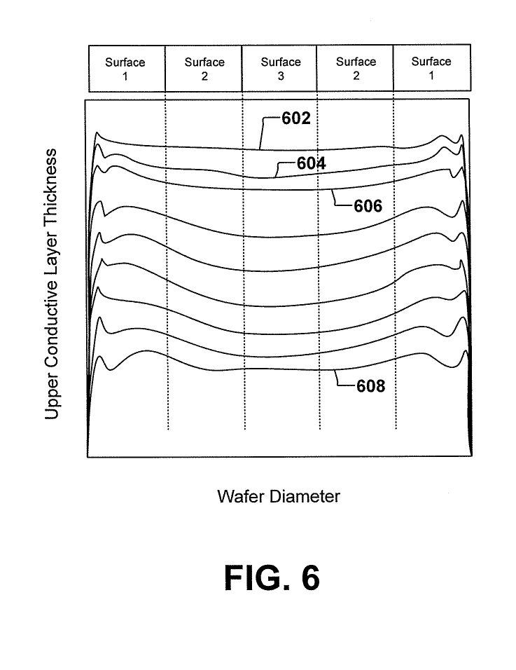

FIG. 6 shows a graph illustrating one manner in which the wafer can be polished. The wafer includes multiple concentric to to-be-polished surfaces, wherein corresponding temperature control elements (not shown) are proximate thereto. When polishing begins, the upper conductive layer on the wafer has a thickness that follows a first profile 602. As this profile is measured, feedback is provided regarding the relative heights or planarities of the respective to-be-polished wafer surfaces. Based on these planarities, the temperatures of the respective temperature control elements can be adjusted in real-time. Hence, as the upper conductive surface is polished, its thickness is reduced over time, and corresponding profiles are measured in time (604, 606, . . . ) until the desired thickness is reached at 608. Throughout this polishing, the temperature of the individual temperature control elements can be independently changed to limit height variation between neighboring to-be-polished wafer surfaces. For example, if a to-be-polished wafer surface is high relative to its neighboring to-be-polished wafer surfaces, its corresponding temperature control element can increase temperature (and/or temperature for the neighboring to-be-polished wafer surfaces can be decreased). Polishing is complete when the upper conductive layer reaches a predetermined thickness at 608.

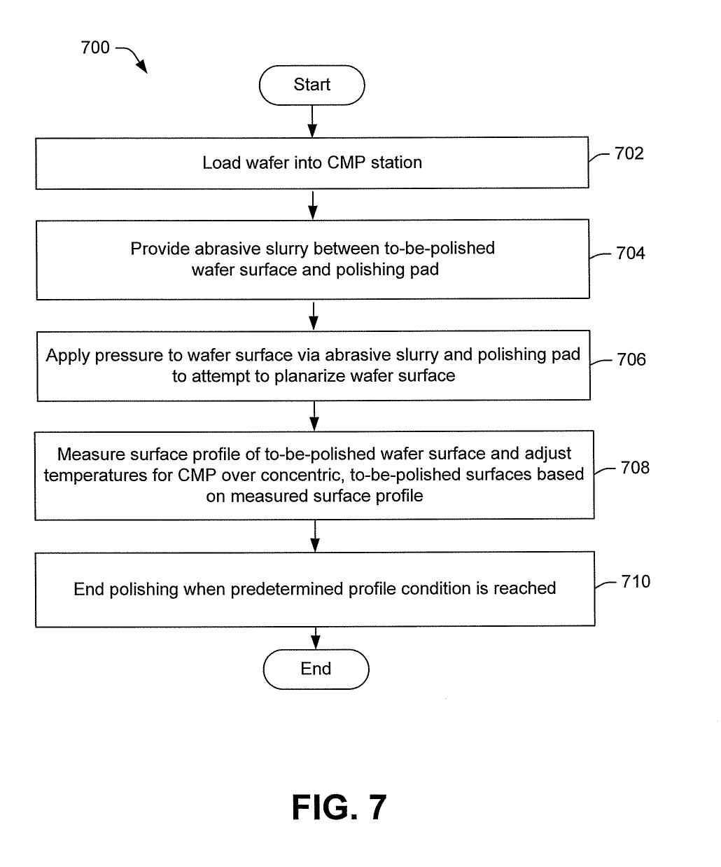

FIG. 7 illustrates another method of planarization in accordance with some embodiments of the present disclosure. While this method and other methods disclosed herein may be illustrated and/or described as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Further, one or more of the acts depicted herein may be carried out in one or more separate acts and/or phases.

As FIG. 7 shows, method 700 starts at 702 when a wafer structure is loaded onto a CMP station. The wafer structure is often retained in a polishing head having multiple pressure zones and multiple temperature control elements. As previously alluded to, the CMP station planarizes wafers (or wafer structures) as part of an overall wafer fabrication process. Each wafer typically includes a number of electrical connections and electrical isolation regions that are established using alternating layers of conductors and insulators.

In step 704, the method provides an abrasive slurry between a wafer surface and a polishing pad.

In 706, the method applies pressure to the wafer surface via the abrasive slurry and polishing pad to attempt to planarize the wafer surface.

In 708, the method measures a surface profile or planarity of the to-be-polished wafer surface and adjusts temperatures for CMP over concentric to-be-polished wafer surfaces based on the measured surface profile.

In 710, polishing for the wafer ends when the surface profile indicates that a predetermined profile is reached. Often, this corresponds to a condition where the upper conductive layer on the wafer reaches a predetermined thickness.

Although the disclosure has been shown and described with respect to a certain aspect or various aspects, equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the disclosure. In addition, while a particular feature of the disclosure may have been disclosed with respect to only one of several aspects of the disclosure, such feature may be combined with one or more other features of the other aspects as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A chemical mechanical polishing (CMP) system, comprising:
a wafer carrier adapted to retain a wafer, the wafer including a plurality of to-be polished wafer surface regions;
a plurality of concentric temperature control elements proximate to the plurality of to-be-polished wafer surface regions, respectively;
a surface planarity analyzer to measure relative heights of the to-be-polished wafer surface regions during polishing; and
a feedback path coupling the surface planarity analyzer to the concentric temperature control elements and adapted to adjust respective temperatures provided by the respective temperature control elements based on the relative heights of the corresponding to-be-polished wafer surface regions measured by the surface planarity analyzer.

2. The CMP system of claim 1, wherein a temperature control element is configured to increase its temperature when a height of a to-be-polished surface region is greater than heights of neighboring to-be-polished surface regions.

3. The CMP system of claim 1, wherein a temperature control element is configured to decrease its temperature when a height of a to-be-polished surface region is less than heights of neighboring to-be-polished surface regions.

4. The CMP system of claim 1, wherein the CMP system further comprises:
multiple variable-pressure elements proximate to a backside of the wafer and arranged to provide independent pressures, respectively, to the backside of the wafer.

5. The CMP system of claim 4, wherein the multiple variable pressure elements are concentrically arranged with respect to one another and are arranged to axially rotate about a spindle axis that is perpendicular to the to-be-polished wafer surface regions.

6. The CMP system of claim 4, wherein the variable-pressure elements include concentric bladders having independently controllable fluid pressures.

7. The CMP system of claim 1, wherein the temperature control elements include concentric bladders having independently controllable temperatures.

8. The CMP system of claim 1, wherein the temperature control elements include respective resistive heating elements whose temperatures are controlled by corresponding currents or voltages.

9. The CMP system of claim 1, wherein the surface planarity analyzer comprises an inductive sensor to measure a height of a to-be-polished wafer surface region by measuring a corresponding Eddy current induced in the wafer while the inductive sensor is over the to-be-polished wafer surface region.

10. A chemical mechanical polishing (CMP) system, comprising:
a platen arranged to rotate about a platen axis;
a polishing pad arranged on the platen;
a slurry dispenser to dispense slurry on the polishing pad;
a wafer carrier adapted to circumferentially retain a wafer and rotate the wafer over the polishing pad such that a plurality of concentric, to-be-polished wafer surface regions are in contact with slurry dispensed on the polishing pad;
a surface planarity analyzer to measure relative heights of the to-be-polished wafer surface regions during polishing; and
a plurality of concentric heating elements proximate to the plurality of to-be-polished wafer surface regions, respectively, and adapted to heat respective slurry regions proximate thereto based on the relative heights of the to-be-polished wafer surface regions measured by the surface planarity analyzer.

11. The CMP system of claim 10, wherein a concentric heating element is configured to increase a temperature of a slurry region when a relative height of a corresponding to-be-polished surface region is greater than relative heights of neighboring to-be-polished surface regions.

12. The CMP system of claim 10, further comprising a controller adapted to:
determine if a height of a to-be-polished surface region, which corresponds to a concentric heating element, is less than heights of neighboring to-be-polished surface regions; and
decrease a temperature provided by the concentric heating element to induce a corresponding temperature decrease in a slurry region proximate to the concentric heating element, wherein the decrease in temperature is relative to that of neighboring slurry regions corresponding to the neighboring to-be-polished surface regions.

13. The CMP system of claim 10, wherein the CMP system further comprises:
a plurality of pressure elements proximate to a backside of the wafer and arranged to provide independent pressures, respectively, between the plurality of to-be-polished wafer surface regions, respectively, and the polishing pad.

14. The CMP system of claim 10, wherein the pressure elements are concentrically arranged with respect to one another and are arranged to axially rotate about a spindle axis that is perpendicular to the to-be-polished wafer surface regions.

15. The CMP system of claim 10, wherein the surface planarity analyzer comprises an inductive sensor to measure a height of a to-be-polished wafer surface region by measuring a corresponding Eddy current induced in the wafer while the inductive sensor is over the to-be-polished wafer surface region.

16. A method of chemical mechanical polishing (CMP), comprising:
loading a wafer, which includes a plurality of concentric, to-be-polished wafer surfaces, onto a CMP station;
providing an abrasive slurry between a polishing pad of the CMP station and the to-be-polished wafer surfaces;
polishing the wafer by applying pressure to the wafer surface via the polishing pad and the abrasive slurry while the wafer and polishing pad are moved with respect to one another;
while the pressure is applied and while the wafer and polishing pad are moved with respect to one another, measuring relative heights of the to-be-polished wafer surfaces; and
adjusting temperatures respectively associated with the to-be-polished wafer surfaces based on the measured relative heights.

17. The method of claim 16, further comprising:
ending the polishing of the wafer when a predetermined height is reached for at least one of the to-be-polished wafer surfaces.

18. The method of claim 16, further comprising:
increasing a temperature associated with a to-be-polished wafer surface when a height of the to-be-polished surface region is greater than heights of neighboring to-be-polished surface regions.

19. The method of claim 16, further comprising:
decreasing a temperature associated with a to-be-polished wafer surface when a height of the to-be-polished surface region is less than heights of neighboring to-be-polished surface regions.

20. The method of claim 16, wherein the relative heights are measured by an inductive sensor that measures Eddy currents induced in the wafer while the inductive sensor travels over the wafer.
